(19) United States
(12) Patent Application Publication
(10) Pub. No.: US 2004/0155364 A1
(43) Pub. Date: Aug. 12, 2004

(54) Reworkable thermosetting resin compositions

(76) Inventor: Takahisa Doba, Yokohama (JP)

Correspondence Address: HENKEL CORPORATION, 1001 Trout Brook Crossing, Rocky Hill, CT, 06067, US

(21) Appl. No.: 10/768,049

(22) Filed: Feb. 2, 2004

Related U.S. Application Data
(62) Division of application No. 10/009,818, filed on Dec. 13, 2001, now abandoned.
Application No. 10/009,818 is a 371 of international application No. PCT/US00/11878, filed on Jun. 16, 2000.
(60) Provisional application No. 60/139,486, filed on Jun. 17, 1999.
(60) Provisional application No. 60/193,392, filed on Mar. 31, 2000.
(60) Provisional application No. 60/193,391, filed on Mar. 31, 2000.
(60) Provisional application No. 60/210,470, filed on Jun. 9, 2000.

(51) Int. Cl. H01L 23/29

(52) U.S. Cl. 257/789

(57) ABSTRACT

The present invention provides a thermosetting resin composition useful as an underfilling sealing resin which enables a semiconductor device, such as a CSP/BGA/LGA assembly which includes a semiconductor chip mounted on a carrier substrate, to be securely connected to a circuit board by short-time heat curing and with good productivity, which demonstrates excellent heat shock properties (or thermal cycle properties); and permits the CSP/BGA/LGA assembly to be easily removed from the circuit board in the event of semiconductor device or connection failure. Similarly, the compositions are useful for mounting onto a circuit board semiconductor chips themselves.

### BACKGROUND OF THE INVENTION

1. Field of the Invention

This invention relates to thermosetting resin compositions useful for mounting onto a circuit board semiconductor devices, such as chip size or chip scale packages (“CSPs”), ball grid arrays (“BGAs”), land grid arrays (“LGAs”) and the like, each of which having a semiconductor chip, such as large scale integration (“LSI”), on a carrier substrate. Similarly, the compositions are useful for mounting onto circuit board semiconductor chips themselves. Reaction products of the compositions of this invention are controllably reworkable when subjected to appropriate conditions.

2. Brief Description of Related Technology

In recent years, the popularity of small-sized electronic appliances, such as camera-integrated video tape recorders (“VTRs”) and portable telephone sets, has made size reduction of LSI devices desirable. As a result of these reduction desires, CSPs, BGAs and LGAs are being used to reduce the size of packages substantially to that of bare chips. Such CSPs, BGAs and LGAs improve the characteristics of the electronic device while retaining many of their operating features, thus serving to protect semiconductor bare chips, such as LSIs, and facilitate testing thereof.

Ordinarily, the CSP/BGA/LGA assembly is connected to electrical conductors on a circuit board by use of a solder connection or the like. However, when the resulting CSP/BGA/LGA/circuit board structure is exposed to thermal cycling, vibration, distortion or is dropped, the reliability of the solder connection between the circuit board and the CSP/BGA/LGA often becomes suspect. Recently, after a CSP/BGA/LGA assembly is mounted on a circuit board, the space between the CSP/BGA/LGA assembly and the circuit board is often now filled with a sealing resin (commonly referred to as underfill sealing) in order to relieve stresses caused by thermal cycling, thereby improving heat shock properties and enhancing the reliability of the structure.

However, since thermosetting resins that form cross linked networks when cured are typically used as the underfill sealing material, in the event of a failure after the CSP/BGA/LGA assembly is mounted on the circuit board, it is difficult to replace the CSP/BGA/LGA assembly without destroying or scrapping the CSP/BGA/LGA assembly-circuit board structure in its entirety.

To that end, techniques for mounting a semiconductor chip on a circuit board are accepted as substantially similar to the mounting of a CSP/BGA/LGA assembly onto a circuit board. One such technique, disclosed in Japanese Laid-Open Patent Publication No. 102343/93, involves a mounting process where a semiconductor chip is fixed and connected to a circuit board by use of a photocurable adhesive. In the event of failure, this semiconductor chip is removable. However, this technique requires the circuit board to be a transparent substrate (e.g., glass) which permits exposure to light from the back side. Since the circuit board is constructed of such a substrate, the resulting structure often exhibits poor heat shock resistance.

Japanese Laid-Open Patent Publication No. 69280/94 discloses a process where a semiconductor chip is fixed and connected to a substrate by use of a resin capable of hardening at a predetermined temperature. In the event of failure, the semiconductor chip is removed from the substrate by softening the resin at a temperature higher than the predetermined temperature. No specific resin is disclosed, and there is no discussion regarding treating the resin that remains on the substrate. Thus, the disclosed process is at best incomplete.

As pointed out in U.S. Pat. No. 5,423,931 (Inoue), it is conventional to use a solvent to remove residual resin from a circuit board. However, swelling the resin with a solvent is a time-consuming process and the corrosive organic acid ordinarily used as the solvent may reduce the reliability of the circuit board. Instead, the '931 patent speaks to a method for removing residual resin by irradiation with electromagnetic radiation.

Japanese Laid-Open Patent Publication No. 251516/93 also discloses a mounting process using a bisphenol A type epoxy resin (CV5183 or CV5183S; manufactured by Matsushita Electric Industrial Co., Ltd.). However, the removal process disclosed does not consistently permit easy removal of the chip, the curing step is lengthy at elevated temperatures, and the process generally results in poor productivity.

Of course, mechanical methods of removing/replacing semiconductor chips from/on a substrate are known, such as by cutting the chip to be removed/replaced. See U.S. Pat. No. 5,355,580 (Tsukada).

Thermoplastic underfill resins are known for use in semiconductor chip attachment. See U.S. Pat. No. 5,783,867 (Belke, Jr.). However, such thermoplastic resins tend to leak under relatively modest temperature conditions. In contrast, thermosetting resins cure into a matrix, which ordinarily have greater thermal stability under end use operating temperatures.

U.S. Pat. No. 5,512,613 (Afzali-Ardakani), U.S. Pat. No. 5,560,934 (Afzali-Ardakani), and U.S. Pat. No. 5,932,682 (Buchwalter), each refer to a reworkable thermoset composition based on a diepoxide component in which the organic linking moiety connecting the two epoxy groups of the diepoxide includes an acid cleavable acyclic acetyl group. With such acid cleavable acyclic acetyl groups forming the bases of the reworkable composition, a cured thermoset need only be introduced to an acidic environment in order to achieve softening and a loss of much of its adhesiveness.

U.S. Pat. No. 5,872,158 (Kuczynski) refers to thermosetting compositions capable of curing upon exposure to actinic radiation, which are based on acetyl diacrylates, and reaction products of which are reported to be soluble in dilute acid.

U.S. Pat. No. 5,760,337 (Iyer) refers to thermally reworkable crosslinked resins to fill the gap created between a semiconductor device and a substrate to which it is attached. These resins are produced by reacting a dienophile (with a functionality greater than 1) with a 2.5-dialkyl substituted furan-containing polymer.

International Patent Publication No. PCT/US98/00858 refers to a thermosetting resin composition capable of sealing underfilling between a semiconductor device including a semiconductor chip mounted on a carrier substrate and a circuit board to which said semiconductor device is electrically connected. The composition includes about 100 parts by weight of an epoxy resin, about 3 to about 60 parts by weight of a curing agent, and about 1 to about 90 parts by weight of a plasticizer. There, the area around the cured thermoset is heated at a temperature of about 190 to about 260° C. for a period of time ranging from about 10 seconds to about 1 minute in order to achieve softening and a loss of much of its adhesiveness.

U.S. Pat. No. 5,948,922 (Ober) and U.S. Pat. No. 5,973,033 (Ober), each refer to a certain class of compounds having tertiary oxycarbonyl linkages, and compositions based on such compounds, which when cured provide thermally decomposable compositions capable of being reworked.

Notwithstanding the state-of-the-art, it would be desirable for an underfilling sealing material to provide good productivity and thermal shock resistance, while allowing the substrates with which it is to be used to be readily processed and easily separated from a semiconductor device without too extreme conditions that may compromise the integrity of the semiconductor devices remaining on the substrate or the substrate itself.

### SUMMARY OF THE INVENTION

The present invention provides a thermosetting resin composition useful as an underfill sealant resin. The composition enables a semiconductor device, such as a CSP/BGA/LGA assembly which includes a semiconductor chip mounted on a carrier substrate, to be securely connected to a circuit board by short-time heat curing and with good productivity, which demonstrates excellent heat shock properties (or thermal cycle properties), and permits the CSP/BGA/LGA assembly to be easily removed from the circuit board in the event of semiconductor device or connection failure. Similarly, a semiconductor chip may be securely connected to, and if necessary removed from, a circuit board using the inventive compositions.

The thermosetting resin composition includes a curable resin component and a curing agent. The curable resin component may be chosen from those having at least two heteroatom-containing carbocyclic structures pending from a core structure, with the core structure containing at least one linkage selected from ether, thioether, carbonate and combinations thereof, which linkage is capable of being reworked under appropriate conditions so as to lose its adhesiveness. One such rework technique involves degrading the cured reaction product of the composition upon exposure to elevated temperature conditions and/or acidic conditions. In addition, the curable resin may be an epoxy resin, at least a portion of which having at least one alkylene oxide residue positioned adjacent at least one terminal epoxy group. Where the curable resin is not an epoxy resin, the inventive composition may include as a separate component an epoxy resin component.

The compositions may also include a monofunctional epoxy coreactant diluent represented by the following structure:

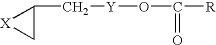

where X represents the heteroatoms, oxygen or sulfur; Y may or may not be present, and when present represents alkyl, alkenyl, aryl and the like; and R represents alkyl, alkenyl, aryl and the like, as well as an inorganic filler component. In addition, where the curing agent is not an anhydride, the inventive compositions may also include a separate anhydride component.

Reaction products of these compositions are capable of being controllably reworked through the softening and loss of their adhesiveness, such as by exposure to temperature conditions in excess of those used to cure the composition.

Although the thermosetting resin composition of the present invention is curable at a relatively low temperature in a short period of time, cured reaction products thereof have excellent heat shock properties and, moreover, can be easily split by the application of force under heated conditions. That is, semiconductor devices or semiconductor chips attached to circuit boards by cured reaction products of the thermosetting resin compositions of this invention can be easily removed by heating the reaction product, allowing it to swell with a solvent, or allowing it to swell with a solvent under heated conditions.

By using the thermosetting resin compositions of this invention, semiconductor devices, such as CSP/BGA/LGA assemblies, or semiconductor chips can be securely connected to a circuit board by short-time heat curing and with good productivity, with the resulting mounting structure demonstrating excellent heat shock properties (or thermal cycle properties). Moreover, in the event of failure, the semiconductor device or semiconductor chip can be easily removed. This makes it possible to reuse the circuit board, thereby achieve an improvement in the yield of the production process and reducing production cost.

The benefits and advantages of the present invention will become more readily apparent after a reading the “Detailed Description of the Invention”, with reference to the figures.

### BRIEF DESCRIPTION OF THE FIGURES

FIG. 1 depicts a cross-sectional view showing an example of a semiconductor device in which the thermosetting resin composition of the present invention is used.

FIG. 2 depicts a cross-sectional view of a semiconductor device which has been removed from the circuit board for repairing purposes.

FIG. 3 depicts a cross-sectional view showing an example of a semiconductor flip chip assembly in which the thermosetting resin composition of the present invention is used.

FIG. 4 depicts a flow diagram of a procedure useful to rework a cured thermosetting resin composition in accordance with the present invention, so as to remove a semiconductor device from a circuit board to which it had been attached.

FIG. 5 depicts a temperature vs. weight loss trace of a thermal gravimetric analysis demonstrating the temperatures at which a composition in accordance with this invention (▪) loses weight by virtue of thermal degradation contrasted to the temperatures at which a composition based on bisphenol-F-type epoxy resin ( ) loses weight by virtue of thermal degradation.

FIG. 6 depicts a temperature vs. weight loss trace of a thermal gravimetric analysis demonstrating the temperatures at which a composition in accordance with this invention (▪) loses weight by virtue of thermal degradation contrasted to the temperatures at which a composition based on bisphenol-F-type epoxy resin (□) loses weight by virtue of thermal degradation.

FIG. 7 depicts a temperature vs. weight loss trace of a thermal gravimetric analysis demonstrating the temperatures at which a composition in accordance with this invention (♦) loses weight by virtue of thermal degradation contrasted to the temperatures at which a composition based on bisphenol-F-type epoxy resin (⋄) loses weight by virtue of thermal degradation.

FIG. 8 depicts a ¹³C NMR spectra of “ANCAMINE” 2337S.

FIG. 9 depicts a FT-IR spectra of “ANCAMINE” 2337S.

### DETAILED DESCRIPTION OF THE INVENTION

The thermosetting resin composition broadly includes a curable resin component and a curing agent.

The curable resin component may be chosen from those having at least two heteroatom-containing carbocyclic structures pending from a core structure, with the core structure containing at least one linkage selected from ether, thioether, carbonate and combinations thereof, which linkage is capable of being reworked under appropriate conditions so as to lose its adhesiveness. One such rework technique involves degrading the cured reaction product of the inventive composition upon exposure to elevated temperature conditions and/or acidic conditions. In addition, the curable resin may be an epoxy resin, at least a portion of which having at least one alkylene oxide residue positioned adjacent at least one terminal epoxy group. Where the curable resin is not itself an epoxy resin, the inventive composition may include as a separate component an epoxy resin component.

In one aspect of the invention, the curable resin may be represented by the following structure:

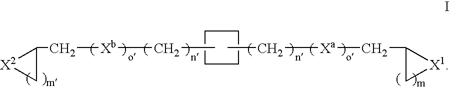

The box may represent one or more structural linkages including aromatic rings(s) or ring system(s), with or without interruption or substitution by one or more heteroatoms, examples of which are given below.

X¹, X² and X^{a} and X^{b} may be the same or different and represent the heteroatoms, oxygen and sulfur. The letter designations, m and m¹, represent integers within the range of 1 to 3, n and n¹ represent integers within the range of 0 to 8, and o and o¹ represent integers within the range of 1 to 3. The box of the core structure of aromatic rings within the curable resin of structure I may be individual aromatic rings, or aromatic ring systems having multiple aromatic units joined in fused ring systems, joined in bi-aryl (such as, biphenyl) or bis-aryl (such as bisphenol A or bisphenol F, or bisphenol compounds joined by a heteroatom) systems, joined in cycloaliphatic-aromatic hybrid ring systems, or joined in oligomeric (such as, novolac-type) systems, examples of which include, among others, naphthalene, anthracene, phenanthracene and fluorene.

For instance, the box may represent the structural linkage

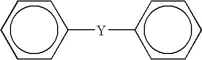

where Y may or may not be present and when present is carbon, or the heteroatom, oxygen or sulfur. Or the box may represent a phenylene group. Either of these representations may bear substitution at one or more locations on the aromatic ring(s) with functional groups ordinarily present on aromatic rings(s), such as alkyl, alkenyl, halo, nitro, carboxyl, amino, hydroxyl, thio, and the like.

For instance, particularly desirable curable resins within structure I include MPG, [bis[4(2,3-epoxy-propylthio)phenyl]-sulfide (CAS Reg. No. 84697-35-8), available commercially from Sumitomo Seika Chemicals Co., Ltd., Osaka, Japan and XBO, xylene bisoxetane (CAS Reg. No. 142627-97-2), available commercially from UBE Industries, Ltd., Tokyo, Japan.

In another aspect of the invention, the curable resin is represented by the following structure:

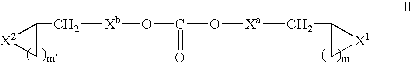

X¹and X² are as above; X^{a} and X^{b} may be the same or different, may or may not be present, and when present represent alkyl, alkenyl, aryl and the like; and the letter designations, m and m¹ are as above.

The heteroatom-containing carbocyclic structures pending from the core structure may be three, four or five membered rings with the heteroatom being an oxygen and/or sulfur atom. These ring structures cross-link with one another under appropriate conditions to form reaction products of the compositions of the present invention.

The carbonate linkage is degradable upon exposure to elevated temperature conditions, with or without the presence of acid. This linkage is capable of degrading to liberate carbon dioxide gas.

The temperature used to effect such degradation of compositions within the scope of the present invention may be as great as 50° C. lower than the temperatures required to degrade ordinary epoxy-based compositions used for this purpose, such as those based on bisphenol-A-type epoxy resins or bisphenol-F-type epoxy resins, which are ordinarily in the vicinity of about 300° C. or more. (See Examples section.)

A particularly desirable curable resin within structure II includes CBO, carbonate bisoxetane (CAS Reg. No. 60763-95-3), available commercially from UBE Industries, Ltd., Tokyo, Japan.

In still another aspect of the invention, the curable resin is an epoxy resin, where at least a portion of such epoxy resin includes an epoxy resin having at least one alkylene oxide residue position adjacent at least one terminal epoxy group. The epoxy resin may be based on mono- or multi-functional aliphatic epoxies, epoxies with a cycloaliphatic ring structure or system, or epoxies with an aromatic ring structure or system, and combinations thereof

For instance the epoxy resin may include any common epoxy resin, such as a multifunctional epoxy resin. Ordinarily, the multifunctional epoxy resin should be included in an amount within the range of about 15% by weight to about 75% by weight of the total of the epoxy resin component. In the case of bisphenol-F-type epoxy resin, desirably the amount thereof should be in the range of from about 35% by weight to about 65% by weight, such as about 40% by weight to about 50% by weight of the total of the epoxy resin component.

Examples of the multifunctional epoxy resin include bisphenol-A-type epoxy resin, bisphenol-F-type epoxy resin (such as RE-404-S from Nippon Kayaku, Japan), phenol novolac-type epoxy resin, and cresol novolac-type epoxy from resin (such as “ARALDITE” ECN 1871 from Ciba Specialty Chemicals, Hawthorne, N.Y.).

Other suitable epoxy resins include polyepoxy compounds based on aromatic amines and epichlorohydrin, such as N,N,N′,N′-tetraglycidyl-4,4′-diaminodiphenyl methane; N-diglycidyl-4-aminophenyl glycidyl ether; and N,N,N′,N′-tetraglycidyl-1,3-propylene bis-4-aminobenzoate.

Among the epoxy resins suitable for use herein also include polyglycidyl derivatives of phenolic compounds, such as those available commercially under the tradename “EPON”, such as “EPON” 828, “EPON” 1001, “EPON”. 1009, and “EPON” 1031 from Shell Chemical Co.; “DER” 331, “DER” 332, “DER” 334, and “DER” 542 from Dow Chemical Co.; and BREN-S from Nippon Kayaku. Other suitable epoxy resins include polyepoxides prepared from polyols and the like and polyglycidyl derivatives of phenol-formaldehyde novolacs, the latter of such as “DEN” 431, “DEN” 438, and “DEN” 439 from Dow Chemical. Cresol analogs are also available commercially under the tradename “ARALDITE”, such as “ARALDITE” ECN 1235, “ARALDITE” ECN 1273, and “ARALDITE” ECN 1299 from Ciba Specialty Chemicals Corporation. SU-8 is a bisphenol-A-type epoxy novolac available from Interez, Inc. Polyglycidyl adducts of amines, aminoalcohols and polycarboxylic acids are also useful in this invention, commercially available resins of which include GLYAMINE” 135, “GLYAMINE” 125, and “GLYAMINE” 115 from F.I.C. Corporation; “ARALDITE” MY-720, “ARALDITE” 0500, and “ARALDITE” 0510 from Ciba Specialty Chemicals and PGA-X and PGA-C from the Sherwin-Williams Co.

An of course combinations of the different epoxy resins are also desirable for use herein.

It is particularly desirable for the portion of the epoxy resin component having at least one alkylene oxide residue positioned adjacent at least one terminal epoxy group to be present in an amount of at least about 5% by weight of the total of epoxy resin component.

Examples of aliphatic epoxies with alkylene oxide residues include, but are not limited to, mono-, di- or multi-functional epoxies containing ether linkages, such as primary, secondary and tertary alkylene diol diglycidyl ethers, and epoxies containing mono- or poly-alkylene oxide residues (such as ethylene oxide, propylene oxide, butylene oxide, pentylene oxide, and hexylene oxide residues).

For instance,

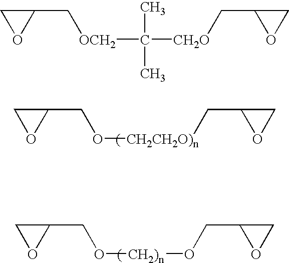

where n is an integer from 1 to about 18, are each appropriate, individually or in combination, for use as at least a portion of the epoxy resin component.

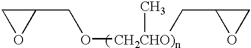

Examples of cycloaliphatic epoxies with alkylene oxide residues include mono-, di- or multi functional cyclohexyl epoxies; hydrated bisphenol A-type epoxies; and hydrated bisphenol F-type epoxies, containing alkylene ether residues. DME-100 (1,4-cyclohexane dimethanol diglycidyl ether, available commercially from New Japan Chemical Co., Ltd.) as shown below is one such example.

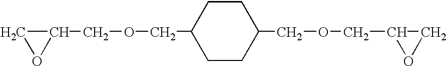

Examples of aromatic epoxies with alkylene oxide residues include mono-, di- or multi-functional epoxies such as bisphenol A type epoxies; bisphenol F type epoxies; phenol novolac type epoxies; and cresol novolac type epoxies, containing alkylene ether residues.

Examples of such epoxies include BEO-60E (ethoxylated bisphenol A di-glycidyl ether, available commercially from New Japan Chemical Co., Ltd.), and BPO-20E (propyloxylated bisphenol A di-glycidyl ether, available commercially from New Japan Chemical Co., Ltd.), which are shown below:

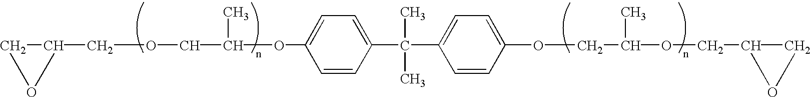

where n is an integer between and about 1 and 20, which for BPO-60E n is 1, and

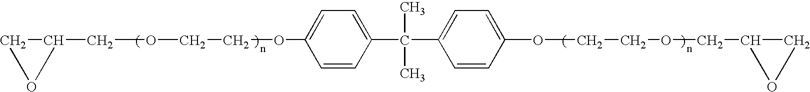

where n is an integer between and about 1 and 20, which for BEO-60E n is 3.

The curable resin component should be present in the composition in an amount which the range of about 10% by weight to about 95% by weight, desirably about 20% by weight to about 80% by weight, such as about 60% by weight

In yet another aspect of the invention,.the epoxy resin is used in combination with a monofunctional epoxy coreactant diluent.

Appropriate monofunctional epoxy coreactant diluents for use herein include those that have a viscosity which is lower than that of the epoxy resin component, ordinarily, less than about 250 cps.

The monofunctional epoxy coreactant diluents should have an epoxy group with an alkyl group of about 6 to about 28 carbon atoms, examples of which include C₆₋₂₈ alkyl glycidyl ethers, C₆₋₂₈ fatty acid glycidyl esters and C₆₋₂₈ alkylphenol glycidyl ethers.

A particularly desirable coreactant diluent is represented by:

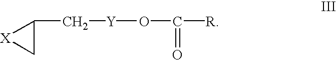

where X represents the heteroatoms, oxygen or sulfur; Y may or may not be present, and when present represents an alkyl (linear, branched, cyclo or bicyclo), or alkenyl (linear, branched, cyclo or bicyclo) and the like linkage of from one to about twenty carbon atoms, linkage and an aryl (one or more aromatic ring(s) or ring system(s)) linkage of from about six to about twenty carbon atoms.

Commercially available monofunctional epoxy coreactant diluents include those from Pacific. Epoxy Polymers, Richmond, Michigan, under the trade designations PEP-6770 (glycidyl ester of neodecandoic acid), PEP-6740 (phenyl glycidyl ether) and PEP-6741 (butyl glycidyl ether).

In the event such a monofunctional epoxy coreactant diluents is included, such coreactant diluent should be employed in an amount of up to about 5% by weight to about 15% by weight, such as about 8% by weight to about 12% by weight, based on the total weight of the composition.

As the curing agent, a variety of materials may be chosen including amine compounds, amide compounds, imidazole compounds, modified amine compounds and modified imidazole compounds (modified compound are also called derivatives thereof).

Examples of the amine compounds include aliphatic polyamines, such as diethylenetriamine, triethylenetetramine and diethylaminopropylamine; aromatic polyamines, such as m-xylenediamine and diaminodiphenylamine; and alicyclic polyamines, such as isophoronediamine and menthenediamine.

Of course, combinations of these amine compounds are also desirable for use in the compositions of the present invention.

Examples of the amide compounds include cyano-functionalized amides, such as dicyandiamide.

Examples of the imidazole compounds include imidazole, isoimidazole, and substituted imidazoles—such as alkyl-substituted imidazoles (e.g., 2-methyl imidazole, 2-ethyl-4-methylimidazole, 2,4-dimethylimidazole, butylimidazole, 2-heptadecenyl-4-methylimidazole, 2-methylimidazole, 2-undecenylimidazole, 1-vinyl-2-methylimidazole, 2-n-heptadecylimidazole, 2-undecylimidazole, 2-heptadecylimidazole, 2-ethyl 4-methylimidazole, 1-benzyl-2-methylimidazole, 1-propyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-guanaminoethyl-2-methylimidazole and addition products of an imidazole and trimellitic acid, 2-n-heptadecyl-4-methylimidazole and the like, generally where each alkyl substituent contains up to about 17 carbon atoms and desirably up to about 6 carbon atoms), and aryl-substituted imidazoles [e.g., phenylimidazole, benzylimidazole, 2-methyl-4,5-diphenylimidazole, 2,3,5-triphenylimidazole, 2-styrylimidazole, 1-(dodecyl benzyl)-2-methylimidazole, 2-(2-hydroxyl-4-t-butylphenyl)-4,5-diphenylimidazole, 2-(2-methoxyphenyl)-4,5-diphenylimidazole, 2-(3-hydroxyphenyl)-4,5-diphenylimidazole, 2-(p-dimethylaminophenyl)-4,5-diphenylimidazole, 2-(2-hydroxyphenyl)-4,5-diphenylimidazole, di(4,5-diphenyl-2-imidazole)-benzene-1,4,2-napthyl-4,5-diphenylimidazole, 1-benzyl-2-methylimidazole, 2-p-methoxystyrylimidazole, and the like, generally where each aryl substituent contains up to about 10 carbon atoms and desirably up to about 8 carbon atoms].

Examples of commercial imidazole compounds are available from Air Products, Allentown, Pa. under the trade designation “CUREZOL” 1B2MZ and from Synthron, Inc., Morganton, N.C. under the trade designation “ACTIRON” NXJ-60.

Of course, combinations of these imidazole compounds are also desirable for use in the compositions of the present invention.

Examples of the modified amine compounds include epoxy amine additives formed by the addition of an amine compound to an epoxy compound, and examples of the modified imidazole compounds include imidazole adducts formed by the addition of an imidazole compound to an epoxy compound.

A commercially available modified amine compound particularly useful herein is “NOVACURE” HX-3722 (an imidazole/bisphenol A epoxy adduct dispersed in bisphenol A epoxy resin, commercially available from Asahi-Ciba Ltd.), and “MY-24” (an imidazole/bisphenol A epoxy adduct, commercially available from Ajinomoto Co., Ltd.).

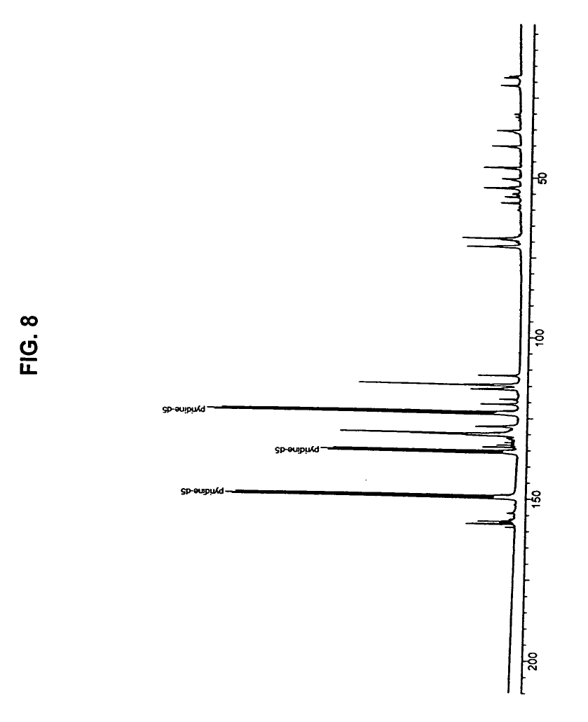

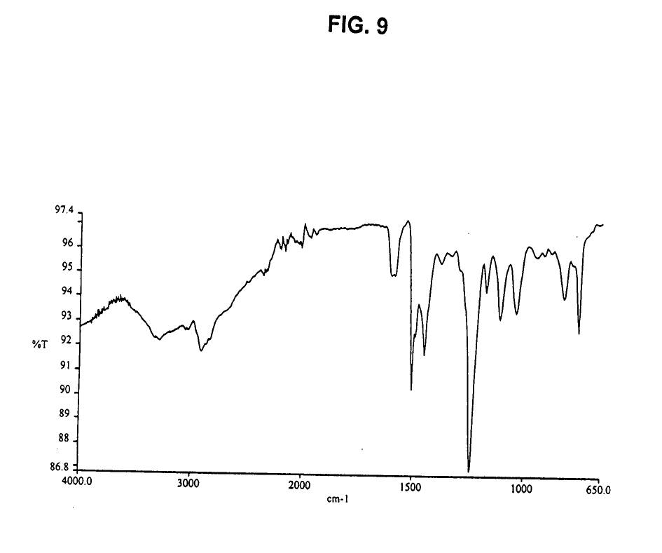

Another such modified amine compound particularly useful herein is available commercially from Air Products and Chemicals, Inc., Allentown, Pennsylvania under the “ANCAMINE” 2337S tradename. “ANCAMINE” 2337S is described by Air Products as a modified aliphatic amine, which is a light yellow powder in appearance with a particle size of 90% <10μ, whose melting point is in the range of 145-172° F. “ANCAMINE” 2337S is reported to have an amine value of 260 (mg KOH/gram), and rapid reactivity above a temperature of 158° F. It is believed that “ANCAMINE” 2337S is a novolac-type resin that has been modified through reaction with aliphatic amines, such as polyamines, pyrazines, pyridines, pyroles and pyrazoles. (See FIGS. 8-9 for characterizing data.) The “ANCAMINE” 2337S itself is substantially insoluble at room temperature in conventional non-basic organic solvents, though was found to be soluble in pyridine.

The curing agent should be present in an amount with the range of about 5% by weight to about 90% by weight, desirably about 20% by weight to about 60% by weight, such as about 50% by weight of the total composition.

The compositions may also include an anhydride component where the curing agent of the compositions is not based on anhydride reactivity, as well as an inorganic filler component.

Appropriate anhydride compounds for use herein include mono- and poly-anhydrides, such as hexahydrophthalic anhydride (“HHPA”) and methyl hexahydrophthalic anhydride (“MHHPA”) (commercially available from Lindau Chemicals, Inc., Columbia, S.C., used individually or as a combination, which combination is available under the trade designation “LINDRIDE” 62C) and 5-(2,5-dioxotetrahydrol)-3-methyl-3-cyclohexene-1,2-dicarboxylic anhydride (commercially available from ChrisKev Co., Leewood, Kans. under the trade designation B-4400). In addition, “MTA-15” (mixture of glycol tris-anhydrotrimeritate and MHHPA, commercially available from New Japan Chemical Co., Ltd.) and “MH-700” (MHHPA, commercially available from New Japan Chemical Co., Ltd.) are particularly desirable choices.

Of course, combinations of these anhydride compounds are also desirable for use in the compositions of the present invention. When used, the anhydride compound may be present in an amount within the range of about 5% by weight to about 90% by weight, desirably about 10% by weight to about 60% by weight, such as about 40% by weight of the total composition.

As an inorganic filler component, many materials are potentially useful. For instance, the inorganic filler component may often include reinforcing silicas, such as fused silicas, and may be untreated or treated so as to alter the chemical nature of their surface. Virtually any reinforcing fused silica may be used.

Particularly desirable ones have a low ion concentration and are relatively small in particle size (e.g., in the range of about 2-10 microns, such as on the order of about 2 microns), such as the silica commercially available from Admatechs, Japan under the trade designation SO-E5.

Other desirable materials for use as the inorganic filler component include those constructed of or containing aluminum oxide, silicon nitride, aluminum nitride, silica-coated aluminum nitride, boron nitride and combinations thereof. When used, the inorganic filler component may be present in an amount within the range of about 5% by weight to about 95% by weight, desirably about 20% by weight to about 60% by weight, such as about 40% by weight of the total composition.

In addition, the composition may also include a flowability agent, such as a silane and/or titanate.

Appropriate silanes for use herein include octyl trimethoxy silane (commercially available from OSI Specialties Co., Danbury, Conn. under the trade designation A-137), and methacryloxy propyl trimethoxy silane (commercially available from OSI under the trade designation A-174).

Appropriate titanates for use herein include titanium IV tetrakis [2,2-bis[(2-propenyloxy)methyl]-1-butanolato-0] [bis(ditridecylphosphito-0), dihydrogen]₂ (commercially available from Kenrich Petrochemical Inc., Bayonne, N.J. under the trade designation KR-55).

When used, the flowability agent may be used in an amount of 0 to about 2 parts by weight, per 100 parts of the epoxy resin.

In addition, adhesion promoters, such as the silanes, glycidyl trimethoxysilane (commercially available from OSI under the trade designation A-187) or gamma-amino propyl triethoxysilane (commercially available from OSI under the trade designation A-1100), may be used.

Cyanate esters may also be used in the inventive compositions. The cyanate esters useful as a component in the inventive compositions may be chosen from dicyanatobenzenes, tricyanatobenzenes, dicyanatonaphthalenes, tricyanatonaphthalenes, dicyanato-biphenyl, bis(cyanatophenyl)methanes and alkyl derivatives thereof, bis(dihalocyanatophenyl)propanes, bis(cyanatophenyl)ethers, bis(cyanatophenyl)sulfides, bis(cyanatophenyl)propanes, tris(cyanatophenyl)phosphites, tris(cyanatophenyl)phosphates, bis(halocyanatophenyl)methanes, cyanated novolac, bis[cyanatophenyl(methylethylidene)]benzene, cyanated bisphenol-terminated thermoplastic oligomers, and combinations thereof.

More specifically, aryl compounds having at least one cyanate ester group on each molecule and may be generally represented by the formula Ar(OCN)m, where Ar is an aromatic radical and m is an integer from 2 to 5. The aromatic radical Ar should contain at least 6 carbon atoms, and may be derived, for example, from aromatic hydrocarbons, such as benzene, biphenyl, naphthalene, anthracene, pyrene or the like. The aromatic radical Ar may also be derived from a polynuclear aromatic hydrocarbon in which at least two aromatic rings are attached to each other through a bridging group. Also included are aromatic radicals derived from novolac-type phenolic resins—i.e., cyanate esters of these phenolic resins. The aromatic radical Ar may also contain further ring-attached, non-reactive substituents.

Examples of such cyanate esters include, for instance, 1,3-dicyanatobenzene; 1,4-dicyanatobenzene; 1,3,5-tricyanatobenzene; 1,3-, 1,4-, 1,6-, 1,8-, 2,6- or 2,7-dicyanatonaphthalene; 1,3,6-tricyanatonaphthalene; 4,4′-dicyanato-biphenyl; bis(4-cyanatophenyl)methane and 3,3′,5,5′-tetramethyl bis(4-cyanatophenyl)methane; 2,2-bis(3,5-dichloro-4-cyanatophenyl)propane; 2,2-bis(3,5-dibromo-4-dicyanatophenyl)propane; bis(4-cyanatophenyl)ether; bis(4-cyanatophenyl)sulfide; 2,2-bis(4-cyanatophenyl)propane; tris(4-cyanatophenyl)-phosphite; tris(4-cyanatophenyl)phosphate; bis(3-chloro-4-cyanatophenyl)methane; cyanated novolac; 1,3-bis[4-cyanatophenyl-1-(methylethylidene)]benzene and cyanated bisphenol-terminated polycarbonate or other thermoplastic oligomer.

Other cyanate esters include cyanates disclosed in U.S. Pat. Nos. 4,477,629 and 4,528,366, the disclosure of each of which is hereby expressly incorporated herein by reference; the cyanate esters disclosed in U.K. Pat. No. 1,305,702, and the cyanate esters disclosed in International Patent Publication WO 85/02184, the disclosure of each of which is hereby expressly incorporated herein by reference. Of course, combinations of these cyanate esters within the imidazole component of the compositions of the present invention are also desirably employed herein.

A particularly desirable cyanate ester for use herein is available commercially from Ciba Specialty Chemicals, Tarrytown, N.Y. under the tradename “AROCY” L10 [1,1-di(4-cyanatophenylethane)].

When used, the cyanate esters may be used in an amount of about 1 to about 20% by weight based on the total amount of the epoxy resin component.

Conventional additives may also be used in the compositions of the present invention to achieve certain desired physical properties of the composition, the cured reaction product, or both.

For instance, it may be desirable in certain instances (particularly where a large volume of inorganic filler component is used) to include a multifunctional epoxy resin reactive diluent, examples of which include those from Pacific Epoxy Polymers, under the trade designations PEP-6752 (trimethylolpropane triglycidyl ether) and PEP-6760 (diglycidyl aniline).

The thermosetting resin composition of the present invention may further contain other additives, such as defoaming agents, leveling agents, dyes and pigments. Moreover, photopolymerization initiators may also be incorporated therein, provided that such initiators do not adversely affect the properties of the composition or reaction products formed therefrom.

The thermosetting resin composition of the present invention may be formulated as a one-part composition, in which all the ingredients are mixed together, or as a two-part composition, in which the epoxy resin and the curing agent are stored separately and mixed thereafter prior to use. Accordingly, the curing agent used in the present invention can generally be any of the curing agents that are used in one-part and two-part epoxy resin formulations, particularly those noted above.

The thermosetting resin compositions according to the present invention are capable of penetrating into the space between the circuit board and the semiconductor device. These inventive compositions also demonstrate a reduced viscosity, at least under elevated temperature conditions, and thus are capable of penetrating into that space. It is desirable to prepare the thermosetting resin composition by selecting the types and proportions of various ingredients to reach a viscosity at 25° C. of 10,000 mPa·s or less, such as 3,000-4,000 mPa·s, so as to improve its ability to penetrate into the space (e.g., of 50 to 500 μm) between the circuit board and the semiconductor device.

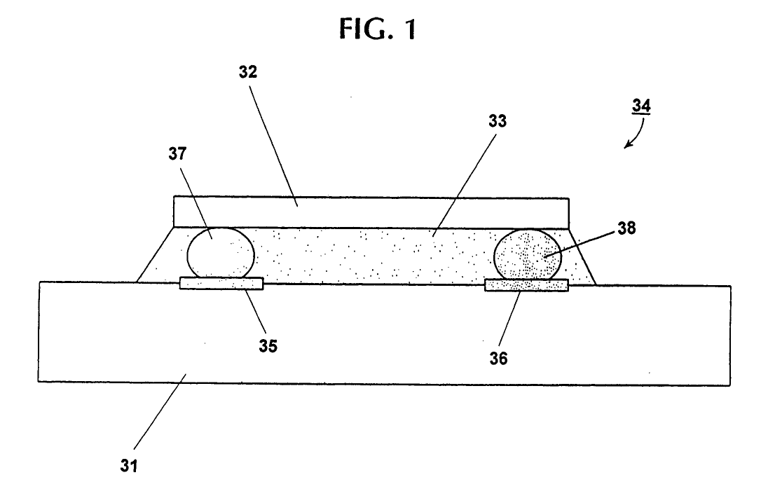

Reference to FIG. 1 shows an example of a semiconductor device mounting structure, such as a CSP, in which the thermosetting resin composition of the present invention is used.

The semiconductor device 4 is one formed by connecting a semiconductor chip (so-called bare chip) 2, such as LSI, to a carrier substrate 1 and sealing the space therebetween suitably with resin 3. This semiconductor device is mounted at a predetermined position of the circuit board 5, and electrodes 8 and 9 are electrically connected by a suitable connection means such as solder. In order to improve reliability, the space between carrier substrate 1 and circuit board 5 is sealed with the cured product 10 of a thermosetting resin composition. The cured product 10 of the thermosetting resin composition need not completely fill the space between carrier substrate 1 and circuit board 5, but may fill it to such an extent as to relieve stresses caused by thermal cycling.

Carrier substrates may be constructed from ceramic substrates made of Al₂O₃, SiN₃ and mullite (Al₂O₃—SiO₂); substrates or tapes made of heat-resistant resins such as polyimides; glass-reinforced epoxy, ABS and phenolic substrates which are also used commonly as circuit boards; and the like.

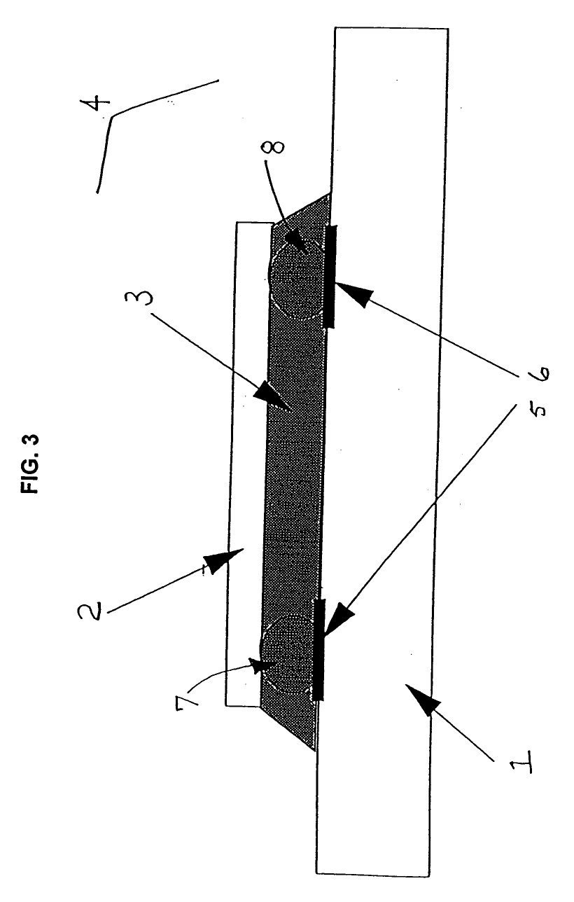

As regards flip chip assemblies, reference to FIG. 3 shows a flip chip assembly in which a semiconductor chip has been mounted onto a circuit board, and the underfilling sealed with a thermosetting resin composition of the present invention.

The flip chip assembly 34 is formed by connecting a semiconductor chip (a bare chip) 32 to a circuit board 31 and sealing the space therebetween suitably with a thermosetting is resin composition 33. This semiconductor device is mounted at a predetermined position on the circuit board 31 and electrodes 35 and 36 are electrically connected by a suitable electrical connection means 37 and 38, such as solder. In order to improve reliability, the space between the semiconductor chip 32 and the circuit board 31 is sealed with a thermosetting resin composition 33 and then cured. The cured product of the thermosetting resin composition should completely fill that space.

No particular limitation is placed on the means for electrically connecting the semiconductor chip to the carrier substrate, and there may be employed connection by a high-melting solder or electrically (or anisotropically) conductive adhesive, wire bonding, and the like. In order to facilitate connections, the electrodes may be formed as bumps. Moreover, in order to improve the reliability and durability of connections, the space between the semiconductor chip and the carrier substrate may be sealed with a suitable resin. The semiconductor devices that can be used in the present invention include CSPs, BGAs, and LGAs.

No particular limitation is placed on the type of circuit board used in the present invention, and there may be used any of various common circuit boards such as glass-reinforced epoxy, ABS and phenolic boards.

Next, the mounting process is described below. Initially, cream solder is printed at the necessary positions of a circuit board and suitably dried to expel the solvent. Then, a semiconductor device is mounted in conformity with the pattern on the circuit board. This circuit board is passed through a reflowing furnace to melt the solder and thereby solder the semiconductor device. The electrical connection between the semiconductor device and the circuit board is not limited to the use of cream solder, but may be made by use of solder balls. Alternatively, this connection may also be made through an electrically conductive adhesive or an anisotropically conductive adhesive. Moreover, cream solder or the like may be applied or formed on either the circuit board or the semiconductor device. In order to facilitate subsequent repairs, the solder, electrically or anisotropically conductive adhesive used should be chosen bearing in mind its melting point, bond strength and the like.

After the semiconductor device is electrically connected to the circuit board in this manner, the resulting structure should ordinarily be subjected to a continuity test or the like. After passing such test, the semiconductor device may be fixed thereto with a resin composition. In this way, in the event of a failure, it is easier to remove the semiconductor device before fixing it with the resin composition.

Then, using a suitable application means such as dispenser, a thermosetting resin composition is applied to the periphery of the semiconductor device. When this composition is applied to the semiconductor device, it penetrates into the space between the circuit board and the carrier substrate of the semiconductor device by capillary action.

Next, the thermosetting resin composition is cured by the application of heat. During the early stage of this heating, the thermosetting resin composition shows a significant reduction in viscosity and hence an increase in fluidity, so that it more easily penetrates into the space between the circuit board and the semiconductor device. Moreover, by providing the circuit board with suitable venting holes, the thermosetting resin composition is allowed to penetrate fully into the entire space between the circuit board and the semiconductor device.

The amount of thermosetting resin composition applied should be suitably adjusted so as to fill the space between the circuit board and the semiconductor device almost completely.

When the above-described thermosetting resin composition is used, it is usually cured by heating at a temperature of about 80° C. to about 150° C. for a period of time of about 5 to about 60 minutes. Thus, the present invention can employ relatively low-temperature and short-time curing conditions and hence achieve very good productivity. The semiconductor device mounting structure illustrated in FIG. 1 is completed in this manner.

In the mounting process using the thermosetting resin composition of the present invention, after the semiconductor device is mounted on the circuit board as described above, the resulting structure is tested with respect to characteristics of the semiconductor device, connection between the semiconductor device and the circuit board, other electrical characteristics, and the state of sealing. In the event a failure is found, repair can be made in the following manner.

The area around the semiconductor device that has failed is heated at a temperature of about 190° C. to about 260° C. for a period of time ranging from about 10 seconds to about 60 seconds. Although no particular limitation is placed on the heating means, local heating is preferred. There may be employed a relatively simple means such as the application of hot air to the failure site.

As soon as the solder is melted and the resin is softened to cause a reduction in bond strength, the semiconductor device is pulled apart.

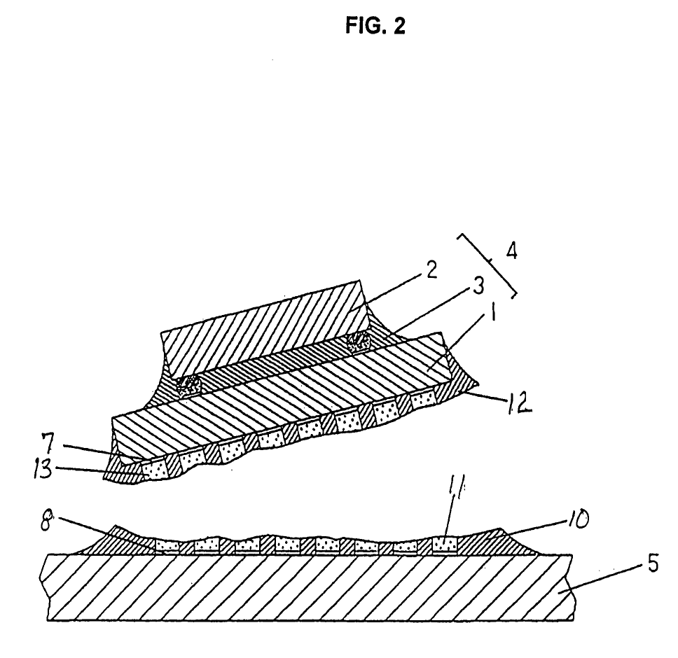

After the semiconductor device 4 is removed as shown in FIG. 2, a residue 12 of the cured reaction product of the thermosetting resin composition and a residue 14 of the solder are left on the circuit board 5. The residue of the cured product of the thermosetting resin composition can be removed, for example, by scraping it off after the residue has been softened by heating it to a predetermined temperature, allowing it to swell with solvent, or allowing it to swell with solvent while heating it to a predetermined temperature.

The residue can be most easily removed by using both heating and solvent. For example, the residue can be scraped off after it has been softened by allowing the residual resin to swell with solvent while keeping the entire circuit board at a temperature of about 100° C. (usually in the range of about 80° C. to about 120° C.).

The solvent used for this purpose is one which causes cured reaction products of the thermosetting resin composition to swell, thereby reducing bond strength to such an extent that the cured material can be scraped off from the circuit board. Useful solvents include organic ones, for example, alkyl chlorides, such as methylene chloride; glycol ethers, such as ethyl cellulose and butyl cellulose; diesters of dibasic acids, such as diethyl succinate; and N-methylpyrrolidone. Of course, appropriate combinations may also be employed.

Where a circuit-protecting resist has already been connected to the circuit board, the chosen solvents should cause no damage to the resist. Desirable solvents with this in mind include glycol ethers and N-methylpyrrolidone.

The residue of the solder can be removed, for example, by use of a solder-absorbing braided wire.

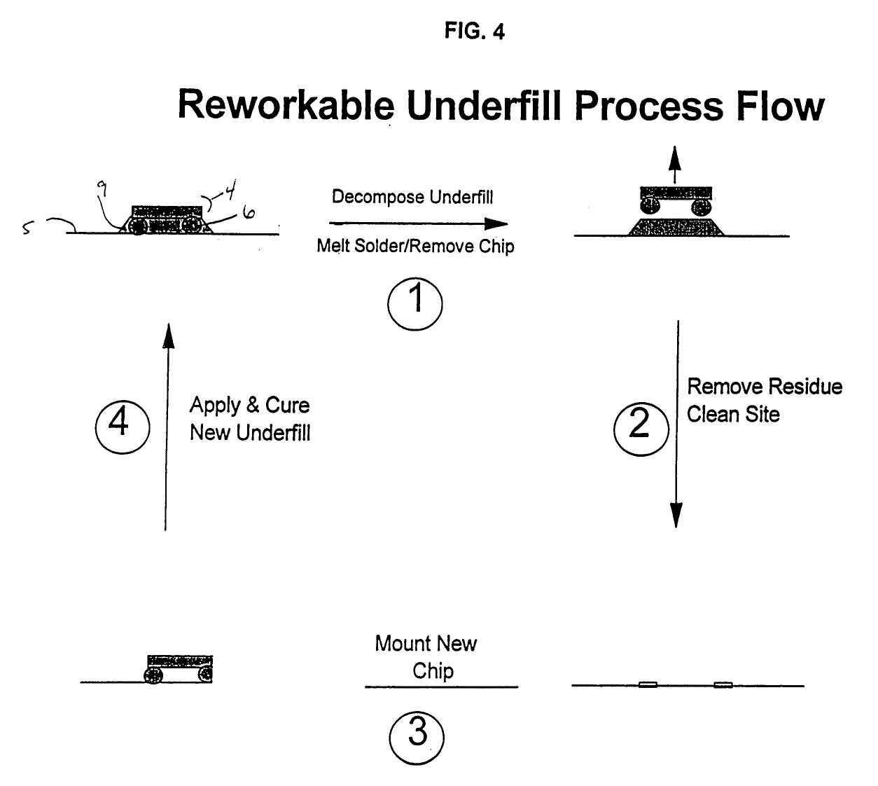

Finally, on the circuit board which has been cleaned according to the above-described procedure, a new semiconductor device may be mounted again in the same manner as described previously. Thus, the repair of the failure site is completed.

Where a failure is found in the circuit board, the semiconductor device can be reused by removing the residue 13 of the cured reaction product of the thermosetting resin composition and the residue 15 of the solder left on the bottom of the semiconductor device in the same manner as described above. (See FIG. 4.)

The invention will be further illustrated by the following non-limiting examples.

### EXAMPLES

### Example 1

### Thermosetting Resin Composition

A thermosetting resin compositions in accordance with the present invention may be prepared from the components as noted below in Tables 1a-1f.

TABLE 1a

| Component | | Sample No./Amt (grams) | | | | | | | |
|---|---|---|---|---|---|---|---|---|---|
| Type | Identity | 1 | 2 | 3 | 4 | 5 | 6 | 7 | 8 |
| Epoxy | BEO-60E | 61.176 | 42.824 | 36.706 | — | — | — | — | — |
| | BPO-20E | — | — | — | 65.488 | 58.939 | 45.842 | 32.744 | 59.002 |
| | DME-100 | — | — | — | — | — | — | — | — |
| Curing | NOVACURE | 6.275 | 4.392 | 3.765. | — | — | — | — | 6.254 |
| Agent | HX-3722 | | | | | | | | |
| Anhydride | MTA-15 | 32.549 | 22.784 | 19.529 | — | — | — | — | 34.744 |
| | MH-700 | — | — | — | 32.417 | 29.175 | 22.692 | 16.208 | — |
| Inorganic | SO-E5 | — | 30 | 40 | — | 10 | 30 | 50 | — |
| Filler | | | | | | | | | |

TABLE 1b

| Component | | Sample No./Amt (grams) | | | | | | | |
|---|---|---|---|---|---|---|---|---|---|
| Type | Identity | 9 | 10 | 11 | 12 | 13 | 14 | 15 | 16 |
| Epoxy | BEO-60E | — | — | — | — | — | — | — | — |
| | BPO-20E | 41.301 | 35.402 | — | — | — | — | — | — |
| | DME-100 | — | — | 48.426 | 44.262 | 44.550 | 40.095 | 35.640 | 31.185 |
| Curing | NOVACURE | 4.378 | 3.752 | — | 6.246 | 5.750 | 5.175 | 4.600 | 4.025 |
| Agent | HX-3722 | | | | | | | | |
| | MY-24 | — | — | 2.082 | — | — | — | — | — |
| Anhydride | MTA-15 | 24.321 | 20.846 | — | — | — | — | — | — |
| | MH-700 | — | — | 49.492 | 49.492 | 48.700 | 43.830 | 38.960 | 34.090 |
| Inorganic | SO-E5 | — | 30 | 40 | — | 10 | 30 | 50 | — |
| Filler | | | | | | | | | |

TABLE 1c

| Component | | Sample No./Amt. (grams) | | | | | | |
|---|---|---|---|---|---|---|---|---|
| Type | Identity | 17 | 18 | 19 | 20 | 21 | 22 | 23 |
| Resin | MPG | 47.80 | 45 | 54.05 | 48.65 | 43.24 | — | — |
| | XBO | — | — | — | — | — | 45.80 | 98 |
| Curing | NOVACURE | 6 | 55 | 2.7 | 2.43 | 2.16 | 6 | — |
| Agent | HX-3722 | | | | | | | |
| | MH-700 | 46.20 | — | 43.25 | 38.92 | 34.60 | 48.20 | — |
| | (Anhydride) | | | | | | | |
| | SI 100 | — | — | — | — | — | — | 2 |
| | (Cationic | | | | | | | |
| | Catalyst) | | | | | | | |
| In- | SO-E5 | — | — | — | 10 | 20 | — | — |
| organic | | | | | | | | |
| Filler | | | | | | | | |

For comparative purposes, Sample Nos. 24-30 were prepared substantially as Sample Nos. 17-23, save for the curable resin, which was replaced with a comparable amount of an epoxy resin—either bisphenol-A-type epoxy resin or bisphenol-F-type epoxy resin. See Table 1d.

TABLE 1d

| Component | | Sample No./Amt. (grams) | | | | | | |
|---|---|---|---|---|---|---|---|---|
| Type | Identity | 24 | 25 | 26 | 27 | 28 | 29 | 30 |
| Epoxy | Bisphenol A | 45 | 48.42 | 43.58 | 38.74 | — | — | — |
| | Bisphenol F | — | — | — | — | 45 | 45.80 | 98 |
| Curing | NOVACURE | 55 | 6.32 | 5.68 | 5.05 | 55 | 6 | — |
| Agent | HX-3722 | | | | | | | |
| | MH-700 | — | 45.26 | 40.74 | 36.21 | — | 48.20 | — |
| | (Anhydride) | | | | | | | |
| | SI 100 | — | — | — | — | — | — | 2 |
| | (Cationic | | | | | | | |
| | Catalyst) | | | | | | | |
| Inorganic | SO-E5 | — | — | 10 | 20 | — | — | — |
| Filler | | | | | | | | |

TABLE 1e

| Component | | Sample No./Amt. (grams) | | | | | | | | |
|---|---|---|---|---|---|---|---|---|---|---|
| Type | Identity | 31 | 32 | 33 | 34 | 35 | 36 | 37 | 38 | 39 |
| Resin | CBO | 40 | 98 | 85.75 | 78.40 | 61.25 | 49 | 36.75 | 19.60 | 12.25 |
| | RE403S | — | — | 12.25 | 19.60 | 36.75 | 49 | 61.25 | 76.40 | 85.75 |
| Curing | NOVACURE | 6 | — | — | — | — | — | — | — | — |
| Agent | HX-3722 | | | | | | | | | |
| | MH-700 | 54 | — | — | — | — | — | — | — | — |
| | (Anhydride) | | | | | | | | | |
| | SI 100 | — | 2 | 2 | 2 | 2 | 2 | 2 | 2 | 2 |
| | (Cationic | | | | | | | | | |
| | Catalyst) | | | | | | | | | |
| Inorganic | SO-E5 | — | — | — | — | — | — | — | — | — |
| Filler | | | | | | | | | | |

For comparative purposes, Sample Nos. 40-48 were prepared as Sample Nos. 31-39, save for the curable resin, which was replaced with a comparable amount of an epoxy resin—either bisphenol-A-type epoxy resin or bisphenol-F-type epoxy resin. The comparative samples are presented in Table 1f.

TABLE 1f

| Component | | Sample No./Amt. (grams) | | | | | | | | |
|---|---|---|---|---|---|---|---|---|---|---|
| Type | Identity | 40 | 41 | 42 | 43 | 44 | 45 | 46 | 47 | 48 |
| Epoxy | Bisphenol A | — | 45 | 48.42 | 43.58 | 38.74 | — | — | — | — |
| | Bisphenol F | 98 | — | — | — | — | 45 | 46 | 41.40 | 36.80 |
| Curing | NOVACURE | — | 55 | 6.32 | 5.68 | 5.05 | 55 | 6 | 5.40 | 4.80 |
| Agent | HX-3722 | | | | | | | | | |
| | MH-700 | — | — | 45.26 | 40.74 | 36.21 | — | 48 | 10 | 20 |
| | (Anhydride) | | | | | | | | | |
| | SI 100 | 2 | — | — | — | — | — | — | — | — |
| | (Cationic | | | | | | | | | |
| | Catalyst) | | | | | | | | | |
| Inorganic | SO-E5 | — | — | — | 10 | 20 | — | — | 10 | 20 |
| Filler | | | | | | | | | | |

TABLE 1g

| Component | | Sample No./Amt (grams) | | |
|---|---|---|---|---|
| Type | Identity | 49 (range) | 50 | 51 |
| Epoxy | Bisphenol A | — | — | 51.4 |
| | Bisphenol F | 48.83-53.97 | 51.4 | — |
| Curing | ANCAMINE | 34.49-38.12 | 36.3 | 36.3 |
| Agent | 2337S | | | |
| Coreactant | Glycidyl | 11.69-12.92 | 12.3 | 12.3 |
| | neodecanoate | | | |

### Physical Properties

In the uncured state, the compositions were observed to have the viscosity values in mPa·s as set forth in Table 2.

In the cured state, reaction products of the composition were observed to have a glass transition temperature (“Tg”) as measured by thermal mechanical analysis (“TMA”), α₁ and α₂, and expansion when cycled between extreme temperatures of about 0° C. and about 140° C. as set forth in Tables 2a-2d.

TABLE 2a

Physical Properties

| Sample | Visc. | Tg | | | Expansion |
|---|---|---|---|---|---|
| No. | (mPa · s) | (° C.) | α₁ | α₂ | (mm) |
| 1 | 1838 | 50.50 | 69.34 | 179.96 | 0.190 |
| 2 | 4534 | 50.12 | 53.20 | 150.14 | 0.160 |
| 3 | 8671 | | | | |
| 4 | 1047 | 66.25 | 64.28 | 188.36 | 0.180 |
| 5 | 1342 | 69.24 | 59.66 | 179.84 | 0.175 |
| 6 | 2521 | 67.36 | 49.26 | 159.2 | 0.175 |
| 7 | 13450 | 68.4 | 36.3 | 136.7 | 0.150 |
| 8 | 5303 | 84.86 | 60.16 | 180.00 | 0.160 |
| 9 | 12110 | — | — | — | — |
| 10 | 21960 | — | — | — | — |
| 11 | 70 | — | — | — | — |
| 12 | 63 | 90.82 | 65.84 | 175.92 | 0.165 |
| 13 | 75 | 83.17 | 65.40 | 180.28 | 0.160 |
| 14 | 95 | 87.14 | 59.71 | 174.56 | 0.160 |
| 15 | 133 | 84.33 | 56.00 | 159.20 | 0.135 |
| 16 | 167 | 87.61 | 49.12 | 147.07 | 0.135 |

TABLE 2b

Physical Properties

| | | | | | Adhesion |
|---|---|---|---|---|---|
| Sample | Visc. | Tg | | | Strength |
| No. | (mPas) | (° C.) | α₁ | α₂ | (N/mm²) |
| 17 | — | — | — | — | — |
| 18 | 3108 | 66.40 | 57.78 | 182.37 | 21.30 |
| 19 | 147.9 | 107.57 | 58.92 | 170.23 | 3.71 |
| 20 | 191.2 | 108.34 | 51.78 | 164.45 | 3.13 |
| 21 | 259.9 | 111.19 | 48.04 | 152.56 | 2.94 |
| 22 | 152.2 | — | — | — | — |
| 23 | — | — | — | — | — |
| 24 | 33490 | 121.61 | 57.12 | 196.61 | 22.61 |
| 25 | 815.6 | 132.31 | 59.62 | 182.99 | 4.42 |
| 26 | 2155 | 148.2 | 52.63 | 167.86 | 4.29 |
| 27 | 2585 | 140.86 | 54.79 | 156.27 | 3.57 |
| 28 | 334.5 | 119.12 | 58.57 | 172.14 | 5.51 |
| 29 | 752.9 | 126.89 | 52.83 | 156.27 | 4.77 |
| 30 | 315.6 | 127.35 | 49.59 | 163.54 | — |

TABLE 2c

| | Physical Properties | | | | |
|---|---|---|---|---|---|
| | | | | | Adhesion |
| Sample | Visc. | Tg | | | Strength |
| No. | (mPa · s) | (° C.) | α₁ | α₂ | (N/mm²) |
| 31 | 12.20 | — | — | — | — |
| 32 | 43.68 | −0.91 | 64.31 | 175.63 | — |
| 33 | — | — | — | — | — |
| 34 | 78.06 | 22.91 | 66.62 | 184.26 | — |
| 35 | — | — | — | — | — |
| 36 | 132.50 | 40.42 | 69.21 | 183.22 | — |
| 37 | — | — | — | — | — |
| 38 | 146.1 | 31.12 | 54.37 | 185.54 | — |
| 39 | — | — | — | — | — |
| 40 | 315.6 | 127.35 | 49.59 | 163.54 | — |
| 41 | 33490 | 121.61 | 57.12 | 196.61 | 22.61 |
| 42 | 815.6 | 132.31 | 59.62 | 182.99 | 4.42 |
| 43 | 2155 | 148.2 | 54.79 | 161.96 | 4.29 |
| 44 | 2585 | 140.86 | 52.63 | 156.27 | 3.57 |
| 45 | 334.5 | 119.12 | 58.57 | 172.14 | 5.51 |
| 46 | 15420 | 120.11 | 55.49 | 182.84 | 20.94 |
| 47 | 752.9 | 126.87 | 52.83 | 167.86 | 4.77 |
| 48 | 892.4 | 129.62 | 48.5 | 157.82 | 4.27 |

TABLE 2d

Physical Properties

| Sample | Visc. | Tg | | | Modulus |
|---|---|---|---|---|---|
| No. | (mPas) | (° C.) | α₁ | α₂ | (N/mm²) |
| 50 | 4000 | 41 | 60 | 195 | 5400 |
| 51 | 8000 | — | — | — | — |

The viscosity of the majority of these samples is suitable for use as an underfill sealant. That is, a viscosity less than about 10,000 mPa·s. The Tg values for the samples listed are suitable for use as an underfill sealant. Though not given in any of Tables 2a-2d, the coefficient of thermal expansion values for the samples were between about 0° C. and about 140° C., which is suitable for use as an underfill sealant.

### Mounting Process

Using cream solder (PS10R-350A-F92C; manufactured by Harima Chemicals, Inc.), a CSP having a package of 10 mm square, an electrode diameter of 0.5 mm, an electrode pitch of 1.0 mm, and a carrier substrate made of alumina was mounted on a 1.6 mm thick glass-reinforced epoxy board having a circuit formed thereon.

Thereafter, the thermosetting resin composition was applied to the periphery of the CSP by means of a dispenser, and then cured by heating in an environment where the temperature was held at about at 150° C. for a period of time of about 60 minutes. The thermosetting resin composition penetrated into the space between the semiconductor device and the circuit board before curing completely.

### Heat Shock Test

Four replicates of Sample Nos. 2 and 8 prepared as described above were exposed to a heat shock test while maintaining the replicates at a temperature of about −40° C. for a period of time of about 10 minutes and thereafter an elevation of temperature to about +125° C. for a period of time of about 10 minutes. After a predetermined number of thermal cycles were reached, the replicates were subjected to a continuity test to confirm the electrical connection between the CSP and the circuit board. The replicates were regarded as acceptable when continuity was confirmed to be at least 800 cycles, and unacceptable when continuity was lost owing to broken lines or the like before this number of cycles was reached. As to the mounting structure of this example, all of the replicates were acceptable even at more than 900 cycles.

### Repair

Using a hot air generator, the area around the CSP fixed to the circuit board with the thermosetting resin composition as described above was heated by applying hot air at 250° C. for 1 minute. Then, the CSP could be easily removed by inserting a metal piece between the CSP and the glass-reinforced epoxy board, and lifting the CSP.

While the glass-reinforced epoxy board was kept at a temperature of about 100° C. by placing it on a hot plate (or by heating it with a far-infrared heater or the like), the resin left on the glass-reinforced epoxy board was allowed to swell with a solvent such as PS-1 (manufactured by Dai-ichi Kogyo Seiyaku Co., Ltd.) or 7360 (manufactured by Loctite Corporation), and then scraped off with a spatula. The solder left on the glass-reinforced epoxy board was removed by use of a solder-absorbing braided wire. Residual trace resin remaining on the glass-reinforced epoxy board was removed with acetone absorbed onto a cloth. The time required for this repairing operation was within about 3 minutes, which was sufficiently short from a practical point of view.

The ease of repair and reworkability of the cured adhesive is expressed below in Tables 3a-3d on a relative scale between 1 and 5, with 1 being an unreworkable cured adhesive and therefore incapable of repair and 5 being a reworkable cured adhesive and therefore easily repairable using the procedure described.

TABLE 3a

| | |
|---|---|
| Sample | Reworkability |

| No. | Heat | Acetone |
|---|---|---|
| 1 | 4 | 3 |
| 2 | 3 | 3 |
| 3 | 2 | — |
| 4 | 4 | 4 |
| 5 | 4 | 3 |
| 6 | 3 | 3 |
| 7 | 3 | 3 |
| 8 | 4 | 3 |
| 9 | 2 | — |
| 10 | 2 | — |
| 11 | 5 | — |
| 12 | 5 | — |
| 13 | 4 | 3 |
| 14 | 4 | 4 |
| 15 | 3 | 3 |
| 16 | 3 | 3 |

TABLE 3b

| Sample | Repairability/ |
|---|---|
| No. | Heat |
| 17 | — |
| 18 | 3.5 |
| 19 | 3 |
| 20 | 2 |
| 21 | 2 |
| 22 | — |
| 23 | — |
| 24 | 1 |
| 25 | 2 |
| 26 | 1 |
| 27 | 1 |
| 28 | 2 |
| 29 | 1 |
| 30 | 2 |

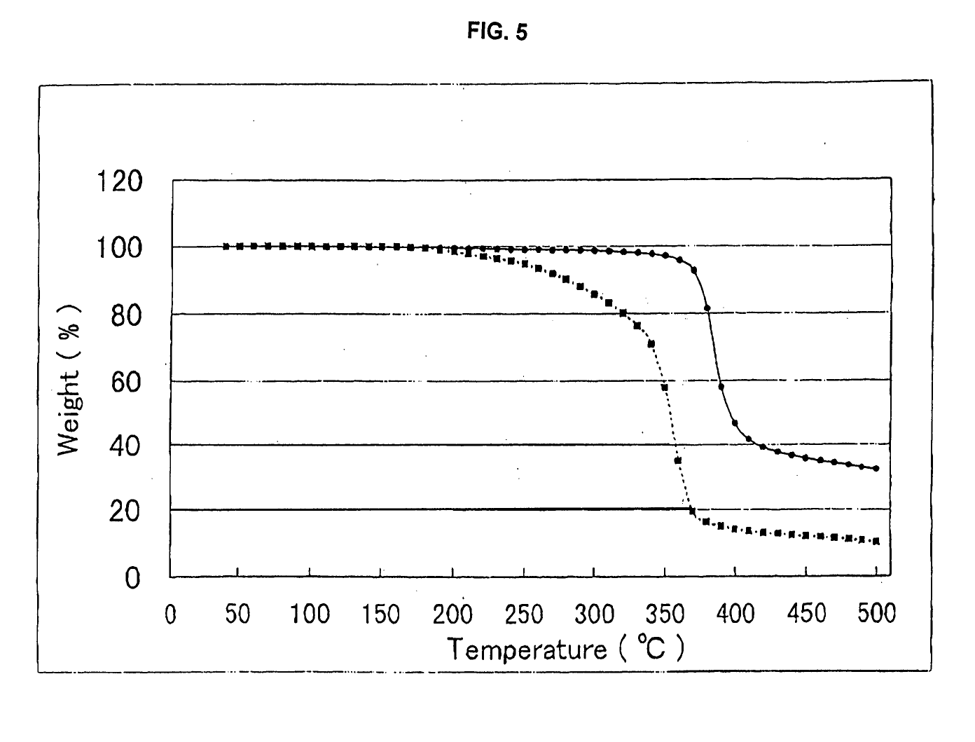

Reference to FIG. 5 shows the temperature range at which a cured reaction product of a XBO-based composition curable through a cationic cure mechanism (Sample No. 23) in accordance with the invention loses weight by virtue of thermal degradation as it is exposed to an increase in temperature contrasted to a cured reaction product of a composition based on bisphenol-F-type epoxy resin curable through a cationic cure mechanism (Sample No. 30).

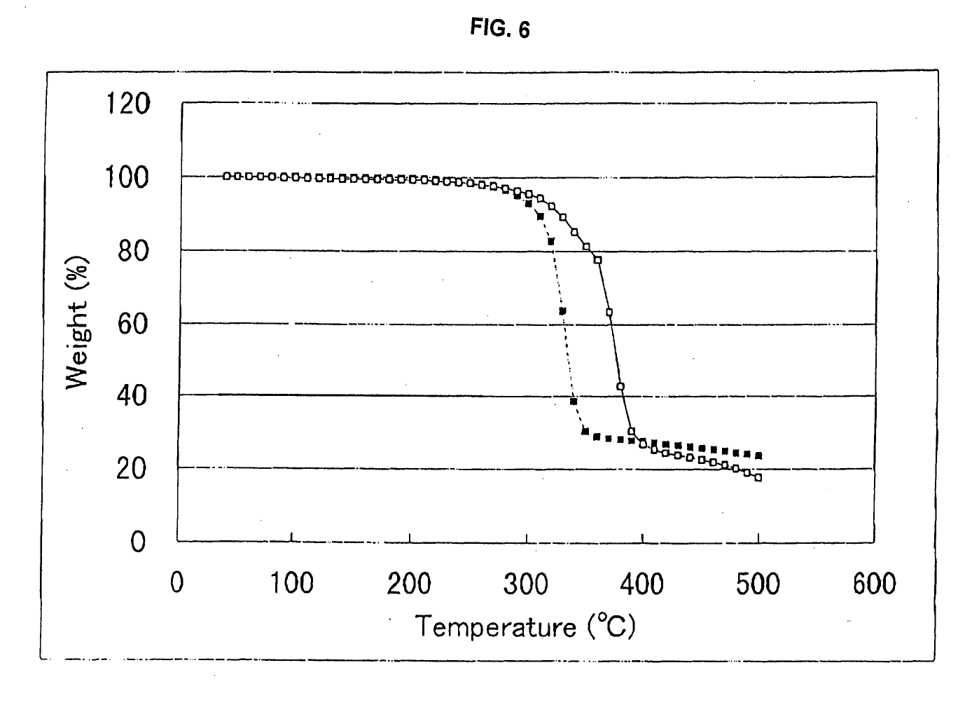

Reference to FIG. 6 shows the temperature range at which a cured reaction product of a MPG-based composition (Sample No. 17) in accordance with the invention loses weight by virtual of thermal degradation as it is exposed to an increase in temperature contrasted to a cured reaction product of a composition based on bisphenol-F-type epoxy resin (Sample No. 29).

TABLE 3c

| Sample | Repairability/ |
|---|---|
| No. | Heat |
| 31 | — |
| 32 | 5 |
| 33 | — |
| 34 | 4 |
| 35 | — |
| 36 | 3.5 |
| 37 | — |
| 38 | 3.5 |
| 39 | — |
| 40 | 2 |
| 41 | 1 |
| 42 | 2 |
| 43 | 1 |
| 44 | 1 |
| 45 | 1 |
| 46 | 2 |
| 47 | 1 |
| 48 | 1 |

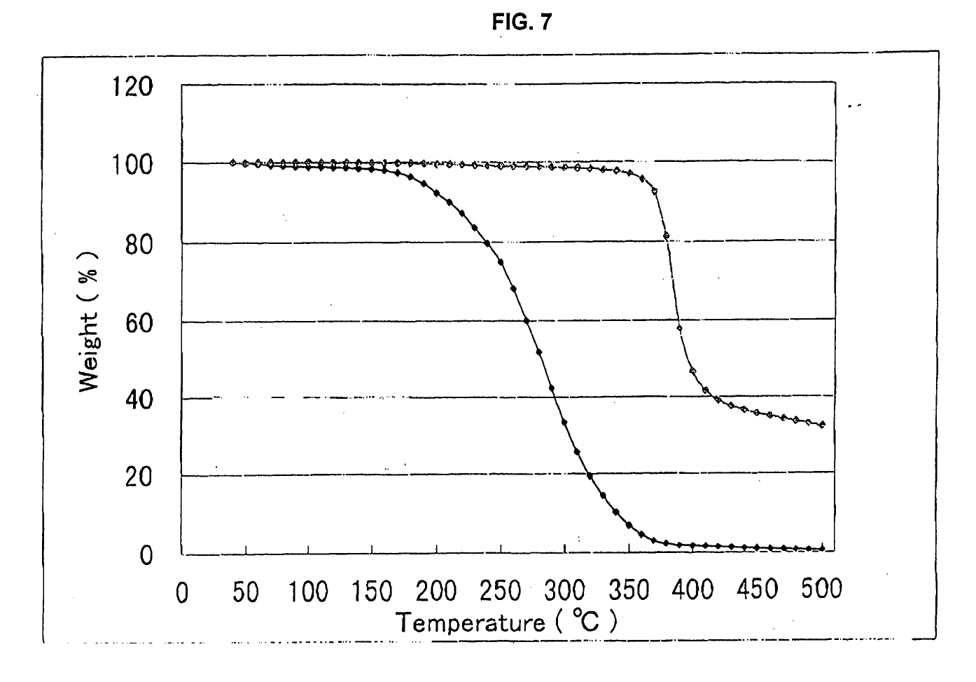

Reference to FIG. 7 shows the temperature range at which a cured reaction product of a CBO-based composition curable through a cationic cure mechanism (Sample No. 32) in accordance with the invention loses weight by virtue of thermal degradation as it is exposed to an increase in temperature contrasted to a cured reaction product of a composition based on bisphenol-F-type epoxy resin curable through a cationic cure mechanism (Sample No. 40).

TABLE 3d

| Sample | Repairability/ |
|---|---|
| No. | Heat |
| 50 | 3.5 |
| 51 | 3 |

The full scope of the invention is measured by the claims.

What is claimed is:

1. A thermosetting resin composition, reaction products of which are controllably degradable, said composition comprising:
(a) a curable resin component selected from the group consisting of curable resins having at least two heteroatom-containing carbocyclic structures pending from a core structure, with the core structure containing at least one ether, thioether or carbonate linkage that is capable of degrading upon exposure to elevated temperature conditions and/or acidic conditions, epoxy resins, at least a portion of which having at least one alkylene oxide residue positioned adjacent at least one terminal epoxy group and the combination of an epoxy resin and a coreactant diluent represented by the structure: 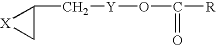
wherein X represents the heteroatoms, oxygen or sulfur; Y may or may not be present, and when present represents alkyl, alkenyl, and aryl; and R represents alkyl, alkenyl, and aryl; and
(b) a curing agent component.

2. The composition of claim 1, further comprising an anhydride component.

3. The composition of claim 1, further comprising an inorganic filler component.

4. The composition of claim 1, wherein the curable resin component is represented by the following structure: 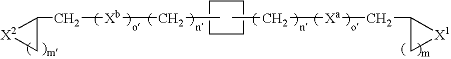
wherein the box represents one or more aromatic ring(s) or ring system(s), with or without interruption or substitution by one or more heteroatoms; X¹, X² X^{a}, and X^{b} may be the same or different and represent oxygen and sulfur; m and m¹ represent integers within the range of 1 to 3; n and n¹ represent integers within the range of 0 to 8; and o and o¹ represent integers within the range of 1 to 3.

5. The composition of claim 4, wherein the box is represented by 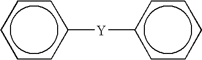
wherein Y may or may not be present, and where present a member selected from the group consisting of carbon, oxygen, sulfur, and phenylene.

6. The composition of claim 4, wherein the box represents a structural linkage selected from the group consisting of individual aromatic rings, oligomeric systems and aromatic ring systems having multiple aromatic units joined in fused ring systems, joined in bi-aryl ring systems, bis-aryl ring systems, or cycloalaphatic-aromatic hybrid ring systems.

7. The composition of claim 1, wherein the curable resin component is represented by the following structure: 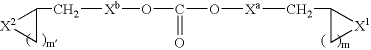
wherein X¹ and X² may be the same or different and represent oxygen and sulfur; X^{a} and X^{b} may be the same or different, may or may not be present, and represent alkyl, alkenyl, and aryl of one to about twenty carbon atoms, or one or more aromatic ring(s) or ring system(s), with or without interruption or substitution by one or more heteroatoms; and m and m¹ represent integers within the range of 1 to 3.

8. The composition of claim 1, wherein the curable resin component is a member selected from the group consisting of MPG [bis[4-(2,3-epoxy-propylthio)phenyl]-sulfide], XBO [xylene bisoxetane], CBO (carbonate bisoxetane), and combinations thereof.

9. The composition of claim 1, wherein the epoxy resin component includes mono- or multi-functional aliphatic epoxies, epoxies with a cycloaliphatic ring structure or system, or epoxies with an aromatic ring structure or system, and combinations thereof.

10. The composition of claim 1, wherein the epoxy resin component includes 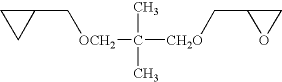 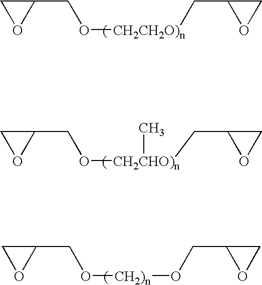
wherein n is an integer from 1 to about 18, 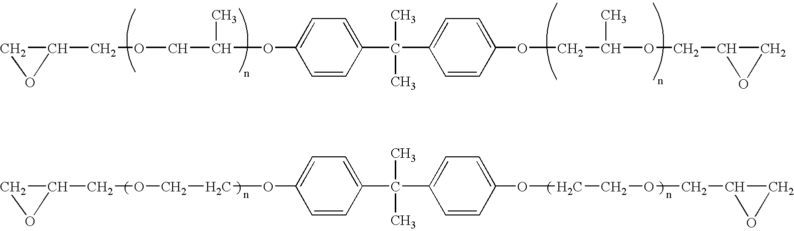
wherein n is as defined above, 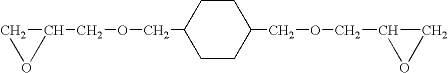
and combinations thereof.

11. The composition of claim 1, wherein the coreactant diluent is represented by the structure: 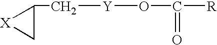
wherein X represents the heteroatoms, oxygen or sulfur; Y may or may not be present, and when present represents a linkage selected from the group consisting of linear, branched, cyclo or bicyclo alkyl or alkenyl of from one or two, respectively, to about twenty carbon atoms, and aryl of one or more aromatic ring(s) or ring system(s) of from about six to about twenty carbon atoms.

12. The composition of claim 1, wherein the coreactant diluent is glycidyl neodecanoate.

13. The composition of claim 1, wherein the curing agent component is a member selected from the group consisting of amine compounds, amide compounds, imidazole compounds, and derivatives and combinations thereof.

14. The composition of claim 13, wherein the amine compounds are selected from the group consisting of aliphatic polyamines, aromatic polyamines, alicyclic polyamines and combinations thereof.

15. The composition of claim 13, wherein the amine compounds are selected from the group consisting of diethylenetriamine, triethylenetetramine, diethylaminopropylamine, xylenediamine, diaminodiphenylamine, isophoronediamine, menthenediamine and combinations thereof.

16. The composition of claim 13, wherein the amide compounds include cyano-functionalized amides.

17. The composition of claim 13, wherein the imidazole compounds are selected from imidazole, isoimidazole, alkyl-substituted imidazoles, and combinations thereof.

18. The composition of claim 13, wherein the imidazole compounds are selected from 2-methyl imidazole, 2-ethyl-4-methylimidazole, 2,4-dimethylimidazole, butylimidazole, 2-heptadecenyl-4-methylimidazole, 2-methylimidazole, 2-undecenylimidazole, 1-vinyl-2-methylimidazole, 2-n-heptadecylimidazole, 2-undecylimidazole, 2-heptadecylimidazole, 2-ethyl 4-methylimidazole, 1-benzyl-2-methylimidazole, 1-propyl-2-methylimidazole, 1-cyanoethyl-2-methylimidazole, 1-cyanoethyl-2-ethyl-4-methylimidazole, 1-cyanoethyl-2-undecylimidazole, 1-cyanoethyl-2-phenylimidazole, 1-guanaminoethyl-2-methylimidazole and addition products of an imidazole and trimellitic acid, 2-n-heptadecyl-4-methylimidazole, aryl-substituted imidazoles, phenylimidazole, benzylimidazole, 2-methyl-4,5-diphenylimidazole, 2,3,5-triphenylimidazole, 2-styrylimidazole, 1-(dodecyl benzyl)-2-methylimidazole, 2-(2-hydroxyl-4-t-butylphenyl)-4,5-diphenylimidazole, 2-(2-methoxyphenyl)-4,5-diphenylimidazole, 2-(3-hydroxyphenyl)-4,5-diphenylimidazole, 2-(p-dimethylaminophenyl)-4,5-diphenylimidazole, 2-(2-hydroxyphenyl)-4,5-diphenylimidazole, di(4,5-diphenyl-2-imidazole)-benzene-1,4, 2-naphthyl-4,5-diphenylimidazole, 1-benzyl-2-methylimidazole, 2-p-methoxystyrylimidazole, and combinations thereof.

19. The composition of claim 13, wherein the modified amine compounds include epoxy amine additives formed by the addition of an amine compound to an epoxy compound.

20. The composition of claim 13, wherein the modified amine compounds include “ANCAMINE” 2337S.

21. The composition of claim 13, wherein the modified amine compounds are novolac-type resin modified through reaction with aliphatic amines.

22. The composition of claim 13, wherein the modified imidazole compounds include imidazole adducts formed by the addition of an imidazole compound to an epoxy compound.

23. The composition of claim 2, wherein the anhydride component is a member selected from the group consisting of hexahydrophthalic anhydride, methyl hexahydrophthalic anhydride, 5-(2,5-dioxotetrahydrol)-3-methyl-3-cyclohexene-1,2-dicarboxylic anhydride, and combinations thereof.

24. The composition of claim 3, wherein the inorganic filler component is a member selected from the group consisting of silica, aluminum oxide, silicon nitride, aluminum nitride, silica-coated aluminum nitride, boron nitride and combinations thereof.

25. A thermosetting resin composition capable of sealing underfilling between a semiconductor device including a semiconductor chip mounted on a carrier substrate and a circuit board to which said semiconductor device is electrically connected, or a semiconductor chip and a circuit board to which said semiconductor chip is electrically connected, reaction products of which are capable of softening and losing adhesivensss comprising:
a curable resin component as set forth in claim 1 in an amount in the range of from about 20% by weight to about 60% by weight, a curing agent component in an amount within the range of from about 1 to about 10% by weight, and optionally an anhydride component in an amount within the range of from about 10 to about 60% by weight, and optionally an inorganic filler component in an amount up to about 60% by weight.

26. Reaction products of the compositions in accordance with any one of claims 1-25.

27. An electronic device comprising a semiconductor device and a circuit board to which said semiconductor device is electrically connected or a semiconductor chip and a circuit board to which said semiconductor chip is electrically connected, assembled using a thermosetting resin composition according to any one of claims 1-25 as an underfill sealant between the semiconductor device and the circuit board or the semiconductor chip and the circuit board, respectively, wherein reaction products of the composition are capable of softening and losing their adhesiveness under exposure to temperature conditions in excess of those used to cure the composition.

28. A method of sealing underfilling between a semiconductor device including a semiconductor chip mounted on a carrier substrate and a circuit board to which said semiconductor device is electrically connected or a semiconductor chip and a circuit board to which said semiconductor chip is electrically connected, the steps of which comprise:
(a) dispensing into the underfilling between the semiconductor device and the circuit board or the semiconductor chip and the circuit board a composition in accordance with any one of claims 1-25; and
(b) exposing the composition as so dispensed to conditions appropriate to cause the composition to form a reaction product.

29. A method of reworking a reaction product of a composition in accordance with any one of claims 1-25, a step of which comprises:
(a) exposing the reaction product to conditions appropriate to cause the reaction product to soften and lose adhesiveness.

30. The method according to claim 29, further comprising the steps of:
(b) removing the semiconductor chip or semiconductor device from the circuit board; and
(c) optionally, cleaning the surface of the circuit board to remove any cured reaction product that remains.
